(19) United States
(12) Patent Application Publication
(10) Pub. No.: US 2010/0267243 A1
(43) Pub. Date: Oct. 21, 2010

(54) PLASMA PROCESSING METHOD AND APPARATUS

(75) Inventors: Masato Kawakami, Yamanashi (JP); Sumie Nagaseki, Yamanashi (JP); Toru Ito, Yamanashi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/680,653

(22) PCT Filed: Sep. 1, 2008
(86) PCT No.: PCT/JP08/65631

§ 371 Date: Mar. 29, 2010

(30) Foreign Application Priority Data
Sep. 28, 2007 (JP) 2007-255660

(51) Int. Cl. H01L 21/3065

(52) U.S. Cl. 438/710; 156/345.24; 257/E21.218

(57) ABSTRACT

In the plasma processing by an electrically negative gas, the in-plane uniformity of plasma processing is enhanced compared to the conventional case by controlling the ion density in the plasma. Not only is a processing gas being an electrically negative gas introduced from a processing gas source 170 into a processing chamber 102 but also an electrically negative gas having electron attachment coefficient greater than that of the processing gas is introduced as an additional gas from an additional gas source 180 to thereby form a plasma. In the plasma formation, the ion density in the plasma is controlled by regulating the flow rate of the additional gas relative to that of the processing gas.

### FIELD OF THE INVENTION

The present invention relates to a plasma processing method and apparatus for performing a predetermined plasma processing on a substrate to be processed.

### BACKGROUND OF THE INVENTION

Generally, in a semiconductor device manufacturing process, various types of processing such as film formation, etching, heat treatment, modification, crystallization and the like are repetitively performed on a substrate to be processed such as a semiconductor wafer (hereinafter, simply referred to as “wafer”), a glass substrate or the like, thereby forming a desired semiconductor integrated circuit.

For example, in an etching process among the various types of processing, a plasma etching method for etching a film formed on a surface of the substrate to be processed is widely used. In this plasma etching method, a predetermined etching gas is introduced as a processing gas through a shower head provided at an upper portion of a processing chamber and then turned into a plasma by application of a high frequency power or the like (see, e.g., Patent Document 1).

To be specific, when an oxide film, e.g., a silicon oxide film (SiO₂ film) formed on a Si wafer or the like, is plasma-etched, a fluorocarbon-based gas such as CF₄ gas or the like which can ensure a fine shape due to its excellent selectivity is widely used as an etching gas. When the fluorocarbon-based gas is turned into a plasma, a plurality of ions (e.g., CF₃⁺) is generated in the plasma, and silicon oxide on the substrate to be processed is selectively etched by the ions thus generated.

However, along with the recent trend towards miniaturization and high integration of semiconductor devices, various attempts have been made to meet the growing demand for improvement of in-plane uniformity of the processing of the substrate to be processed. For example, a processing gas may be introduced through different parts of the processing chamber by dividing the above-described shower head into a central region and a peripheral region. Accordingly, the processing gas can be introduced into the processing chamber while changing the type or the concentration of the processing gas between the central region and the peripheral region. As a result, the in-plane uniformity of the plasma processing can be improved.

Patent Document 1: Japanese Patent Application Publication No. 1994-196452

However, it has been found that when an electrically negative gas such as the aforementioned fluorocarbon-based gas is used as a processing gas, the ion density in the plasma tends to become partially uneven regardless of the location where the processing gas is introduced. This tendency is considered as one of the obstacles in improving the intra-plane uniformity.

In other words, when an electrically negative gas is used as a processing gas, the ion density in the plasma of the processing gas cannot be controlled even if the processing gas is introduced through different parts of the processing chamber while changing the flow rate or the concentration thereof. For that reason, it is difficult to further improve the in-plane uniformity.

### SUMMARY OF THE INVENTION

Therefore, the present invention has been developed to solve the above-described problems, and it is an object of the present invention to provide a plasma processing method and apparatus capable of controlling an ion density in a plasma during plasma processing by using an electrically negative gas and hence improving in-plane uniformity of the plasma processing compared to the conventional case.

As a result of various tests, the present inventors have found that when the processing gas is an electrically negative gas, the ion density in the plasma can be controlled by adding to the processing gas a very small amount of an electrically negative gas having an electron attachment coefficient greater than that of the processing gas. In other words, it has been found that when the processing gas is an electrically negative gas, electrons having low energy are attached to the processing gas, so that a large amount of negative ions is generated and the in-plane distribution of negative ions becomes substantially the same as that of positive ions.

As a result, it has been concluded that the in-plane distribution of positive ions can be controlled by controlling the in-plane distribution of the negative ions that can be achieved by regulating the flow rate of the additional gas. To do so, the amount of negative ions is increased by adding to the processing gas an electrically negative gas as an additional gas having an electron attachment coefficient greater than that of the processing gas. That is, the ion density in the plasma can be controlled by regulating the flow rate of the electrically negative gas as the additional gas. The present invention has been conceived from the above conclusion.

In order to solve the above-described problems, in accordance with an aspect of the present invention, there is provided a plasma processing method for performing a predetermined plasma processing on a substrate to be processed by using a plasma generated by introducing as a processing gas an electrically negative gas into a processing chamber, wherein as an additional gas an electrically negative gas having an electron attachment coefficient greater than that of the processing gas is introduced together with the processing gas into the processing chamber to thereby generate the plasma, and an ion density in the plasma is controlled by regulating a flow rate of the additional gas relative to that of the processing gas.

In order to solve the above-described problems, in accordance with another aspect of the present invention, there is provided a plasma processing apparatus for performing a predetermined plasma processing on a substrate to be processed by using a plasma generated by introducing as a processing gas an electrically negative gas into a processing chamber.

The plasma processing apparatus includes: a processing gas supply system for supplying the processing gas into the processing chamber; an additional gas supply system for supplying as an additional gas an electrically negative gas having an electron attachment coefficient greater than that of the processing gas into the processing chamber; and a control unit for controlling an ion density in the plasma by regulating a flow rate of the additional gas relative to that of the processing gas while generating the plasma by introducing into the processing chamber the processing gas and the additional gas from the processing gas supply system and the additional gas supply system, respectively.

In accordance with the method or the apparatus of the present invention, the plasma is generated by introducing into the processing chamber the electrically negative gas as the processing gas and as the additional gas the electrically negative gas having an electron attachment coefficient greater than that of the processing gas, so that the negative ions in the plasma can be increased. At that time, by regulating the flow rate of the additional gas, the in-plane distribution of the negative ions in the plasma can be controlled and, further, the in-plane distribution of the positive ions that follows the in-plane distribution of the negative ions can also be controlled. Accordingly, the ion density in the plasma can be controlled, and this enables ions to uniformly act on the entire substrate to be processed. As a result, the in-plane uniformity of the plasma processing can be enhanced compared to the conventional case.

Further, the flow rate of the additional gas introduced into the processing chamber may be smaller than or equal to 1/10 of the flow rate of the processing gas. The ion density in the plasma can be controlled only by adding a very small amount of the additional gas to the processing gas. Further, the in-plane uniformity of the plasma processing can be enhanced compared to the conventional case by controlling the flow rate of the additional gas to be smaller than or equal to about 1/10 of the flow rate of the processing gas.

Further, the processing gas may be a fluorocarbon-based gas. In that case, the in-plane distribution of the negative ions in the plasma can be controlled by adding the additional gas selected from, e.g., NF₃ gas, SF₆ gas and F₂ gas.

Further, throughout this specification, 1 mTorr is equivalent to (10⁻³×101325/760) Pa; 1 Torr is equivalent to (101325/760) Pa, and 1 sccm is equivalent to (10⁻⁶/60) m³/sec.

### EFFECTS OF THE INVENTION

In accordance with the present invention, in-plane uniformity of an etching rate of a substrate to be processed can be enhanced compared to the conventional case by uniformly distributing negative ions in the plasma.

### BRIEF DESCRIPTION OF THE DRAWINGS

FIG. 1 is a vertical cross sectional view showing a configuration example of a plasma processing apparatus in accordance with an embodiment of the present invention.

FIG. 2 provides a graph illustrating an in-plane distribution of an etching rate in case of etching a silicon oxide film on a wafer by using a plasma generated from only a processing gas with the use of the plasma processing apparatus shown FIG. 1.

FIG. 3 explains a distribution of negative ions in the plasma generated from the processing gas.

FIG. 4 presents a graph describing in-plane distributions of etching rates of a silicon oxide film in case of generating a plasma while changing a flow rate of NF₃ gas added to CF₄ gas.

FIG. 5 represents a graph depicting in-plane distributions of etching rates of a resist film in case of generating a plasma while changing a flow rate of NF₃ gas added to CF₄ gas.

FIG. 6 offers a graph showing in-plane distributions of etching rates of a silicon oxide film in case of generating a plasma while changing a flow rate of SF₆ gas added to CF₄ gas.

FIG. 7 sets forth a graph illustrating in-plane distributions of etching rates of a resist film in case of generating a plasma while changing a flow rate of SF₆ gas added to CF₄ gas.

### DETAILED DESCRIPTION OF THE EMBODIMENTS

Hereinafter, embodiments of the present invention will be described in detail with reference to the accompanying drawings. Further, like reference numerals will be given to like parts having substantially the same functions throughout the specification and the drawings, and redundant description thereof will be omitted.

### Configuration Example of Plasma Processing Apparatus

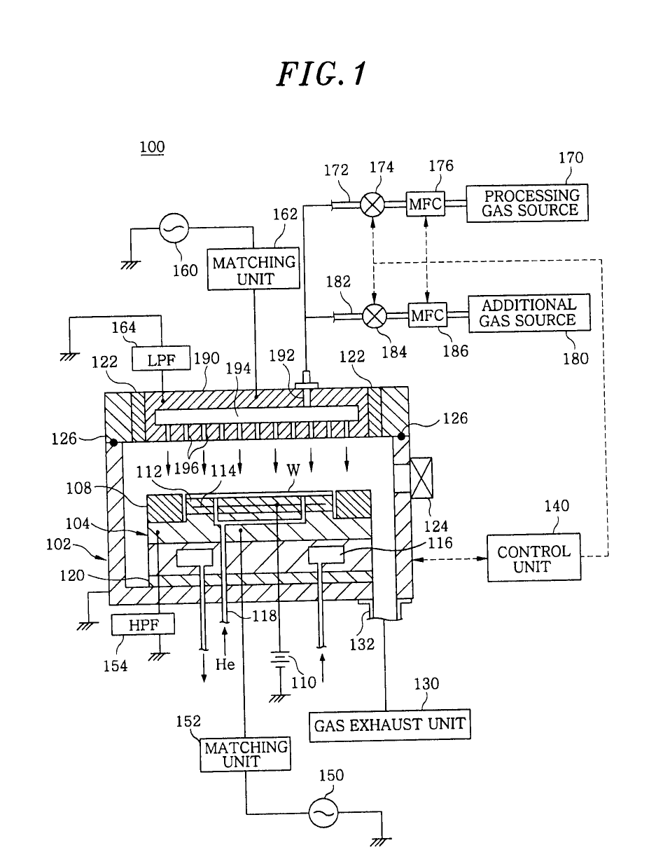

First of all, a configuration example of a plasma processing apparatus in accordance with an embodiment of the present invention will be described. Herein, a parallel plate-type plasma processing apparatus will be described as an example. In the parallel plate-type plasma processing apparatus, an upper electrode and a lower electrode (susceptor) are disposed to face each other in a processing chamber, and a processing gas is supplied through the upper electrode into the processing chamber. FIG. 1 is a cross sectional view showing a schematic configuration of a plasma processing apparatus 100 in accordance with the embodiment of the present invention.

The plasma processing apparatus 100 includes: a processing chamber 102 made of a conductive material, e.g., aluminum or the like; a lower electrode (susceptor 104) provided on a bottom surface of the processing chamber 102 and serving as a mounting table for mounting thereon a wafer W as a substrate to be processed; and an upper electrode 190 disposed to face the lower electrode 104 in parallel.

A first high frequency power supply 150 is connected to the lower electrode 104 via a matching unit 152, and a second high frequency power supply 160 for outputting a high frequency power having a frequency higher than that outputted from the first high frequency power supply 150 is connected to the upper electrode 190 via a matching unit 162. Further, a high pass filter (HPF) 154 is connected to the lower electrode 104, and a low pass filter (LPF) 164 is connected to the upper electrode 190.

A focus ring 108 is disposed at an outer peripheral portion of a top surface of the lower electrode 104 to surround a periphery of the wafer W to thereby facilitate to confine a plasma on the wafer W. An electrostatic chuck 112 is provided on the top surface of the lower electrode 104, and has therein an electrode 114 connected to a high voltage DC power supply 110. When a high DC voltage is applied from the high voltage DC power supply 110 to the electrode 114, an electrostatic adsorptive force is generated around the electrostatic chuck 112. As a consequence, the wafer W can be attracted to and held on the electrostatic chuck 112.

Moreover, a temperature control unit 116 for temperature control is provided in the lower electrode 104 to control a temperature of the wafer W to be kept at a predetermined level. The temperature control unit 116 is configured to control a temperature of the lower electrode 104 by circulating a coolant in a coolant chamber formed in the lower electrode 104, for example.

In addition, a heat transfer medium path 118 is formed in the lower electrode 104, wherein the heat transfer medium path 118 has a plurality of openings on the top surface of the lower electrode 104. Further, openings corresponding to the openings of the heat transfer medium path 118 are formed in the electrostatic chuck 112, so that a backside gas, e.g., He gas, as a heat transfer medium can be supplied into a fine gap between the wafer W and the electrostatic chuck 112. As a consequence, the heat transfer between the lower electrode 104 and the wafer W is facilitated.

An insulating plate 120 is provided between the bottom surface of the lower electrode 104 and the bottom surface of the processing chamber 102 to thereby insulate the lower electrode 104 and the processing chamber 102 from each other. Further, the lower electrode 104 can be configured to move vertically by an elevation mechanism (not shown) in a state where a bellows made of, e.g., aluminum, is provided between the insulating plate 120 and the bottom surface of the processing chamber 102. By using this mechanism, the gap between the upper electrode 190 and the lower electrode 104 can be suitably controlled depending on the types of the plasma processing.

A gas exhaust port 132 is formed on the bottom surface of the processing chamber 102. A gas exhaust unit 130 is connected to the gas exhaust port 132 to exhaust the inside of the processing chamber 102, so that the inside of the processing chamber 102 can be maintained at a predetermined vacuum level.

The upper electrode 190 is connected to a processing gas supply system including a processing gas source 170, a processing gas supply line 172, a valve 174 and a mass flow controller (MFC) 176 and an additional gas supply system including an additional gas source 180, an additional gas supply line 182, a valve 184 and a mass flow controller (MFC) 186, the processing gas supply system and the additional gas supply system being arranged in parallel with each other.

To be specific, the upper electrode 190 is connected to the processing gas source 170 through the processing gas supply line 172, and also is connected to the additional gas source 180 through the additional gas supply line 182. Moreover, the valve 174 and the mass flow controller 176 are disposed in the processing gas supply line 172, and the valve 184 and the mass flow controller 186 are disposed in the additional gas supply line 182. The above components are under the control of the control unit 140, so that the flow rate of the processing gas and that of the additional gas introduced into the processing chamber 102 are controlled.

A predetermined processing gas is supplied from the processing gas source 170, and a predetermined additional gas is supplied from the additional gas source 180. The processing gas and the additional gas used in this embodiment are electrically negative gases having components which easily capture electrons to thereby produce negative ions. In other words, the processing gas has a relatively large electron attachment coefficient indicating a degree of easiness of electron attachment to molecules. Herein, the additional gas is characterized in that it has an electron attachment coefficient greater than that of the processing gas. That is, the additional gas is an electrically negative gas that produces negative ions much more easily than the processing gas.

As for the processing gas, there may be used, e.g., fluorocarbon-based gas (CₓF_{y}, CₓH_{y}F_{z} or the like), O₂ gas, Ar gas, N₂ gas or the like. Each of these gases or any gas mixture of them may be used as the processing gas. The fluorocarbon-based gas includes a gas containing at least F atoms, e.g., CF₄ gas, C₄F₆ gas, C₅F₈ gas, C₄F₈ gas, CHF₃ gas, CH₂F₂ gas or the like. Moreover, as for the additional gas, there may be used, e.g., NF₃ gas, SF₆ gas, F₂ gas or the like. Herein, the case where CF₄ gas and NF₃ gas are respectively used as the processing gas and the additional gas will be described as an example. Further, the operation effect obtained by adding the additional gas to the processing gas will be described later.

The upper electrode 190 in accordance with the embodiment of the present invention is of a pre-mix type in which the processing gas and the additional gas are mixed and then supplied into the processing chamber 102. However, there may be used, instead of the upper electrode 190, an upper electrode of a post-mix type in which the gases are supplied into the processing chamber 102 separately from each other.

Moreover, the processing gas supply system depicted in FIG. 1 may be configured as a single system when a single gas is supplied, e.g., when only CF₄ gas is supplied as an etching processing gas, or may be configured as multiple systems when a gaseous mixture of two or more gases is supplied, e.g., when a gaseous mixture of CF₄ gas and Ar gas is supplied as an etching processing gas. Besides, another system may be additionally provided when an oxygen-based gas (e.g., single O₂ gas) is independently supplied as a processing gas for another processing, e.g., cleaning of the processing chamber in addition to the processing gas for etching process.

The upper electrode 190 is attached to a ceiling portion of the processing chamber 102 via a shield ring 122 for covering a peripheral portion of the upper electrode 190. In addition, the ceiling portion is configured as an openable cover, and a sealing member 126, e.g., an O-ring or the like, for maintaining airtightness is provided between the cover and the sidewall.

Formed at the upper electrode 190 is a gas inlet port 192 for introducing the processing gas and the additional gas respectively through the processing gas supply line 172 and the additional gas supply line 182. Moreover, the upper electrode 190 has therein a diffusion space 194 for diffusing the processing gas and the additional gas introduced through the gas inlet port 192.

Besides, a plurality of gas supply openings 196 for supplying the processing gas and the additional gas from the diffusion space 194 into the processing chamber 102 is formed in the upper electrode 190. Each of the gas supply openings 196 is provided to supply the processing gas and the additional gas to the entire space between the wafer W mounted on the lower electrode 104 and the upper electrode 190.

Further, a cooling mechanism (not shown) is provided at the upper electrode 190. To be specific, a chiller path (not shown) is formed, e.g., outside the diffusion space 194. The temperature of the upper electrode 190 can be controlled (cooled) by circulating a temperature-controlled coolant through the chiller path.

When the processing gas from the processing gas source 170 and the additional gas from the additional gas source 180 are supplied to the upper electrode 190, the processing gas and the additional gas are supplied to the diffusion space 194 through the gas inlet port 192. The above supplied gases are diffused into the diffusion space 194, and then are injected through the gas supply openings 196 toward the lower electrode 104 in the processing chamber 102.

A gate valve 124 for opening and closing a loading/unloading port of the wafer W is provided on the sidewall of the processing chamber 102. By opening the gate valve 124, the wafer W can be loaded into or unloaded from the processing chamber 102.

The plasma processing apparatus 100 further includes a control unit 140 for controlling an entire operation of the apparatus. The control unit 140 executes a predetermined program based on predetermined setting information and controls operations of the valves 174 and 184, the mass flow controllers 176 and 186 and those of other components of the apparatus. Accordingly, an etching process of a predetermined film on the wafer W can be performed. Further, conditions in the processing chamber 102 can be controlled, and the cleaning or the like can be carried out.

### Operation Example of Plasma Processing Apparatus

In the plasma processing apparatus 100 configured as described above, in order to etch, e.g., a silicon oxide film, a silicon nitride film, a poly silicon film or the like formed on the wafer W, the wafer W is loaded into the processing chamber 102 by opening the gate valve 124, and then is mounted on the lower electrode 104.

After the wafer W is loaded into the processing chamber 102, the gate valve 124 is closed and the gas exhaust unit 130 is operated to maintain the inside of the processing chamber 102 to a predetermined vacuum level. At this time, a backside gas, e.g., He gas, is supplied to the electrostatic chuck 112 through the heat transfer medium path 118, so that the wafer W is effectively cooled by increasing a thermal conductivity between the electrostatic chuck 112 and the wafer W. Further, temperatures of the upper electrode 190, the lower electrode 104 and the sidewall of the processing chamber 102 are controlled to be maintained at predetermined levels, respectively.

Moreover, the processing gas from the processing gas source 170 and the additional gas from the additional gas source 180 are introduced into the processing chamber 102 at respective predetermined flow rates. Further, predetermined high frequency powers are supplied to the upper electrode 190 and the lower electrode 104. Accordingly, a plasma is generated in the space between the upper electrode 190 and the wafer W by the processing gas and the additional gas, and a predetermined film on the wafer W is etched by ions (e.g., mainly CF₃⁺) generated from the plasma. Upon the completion of the etching, the processed wafer W is unloaded from the processing chamber 102 in the reverse sequence of the loading process. The same processes are performed to a predetermined number of unprocessed wafers W.

(Etching Result)

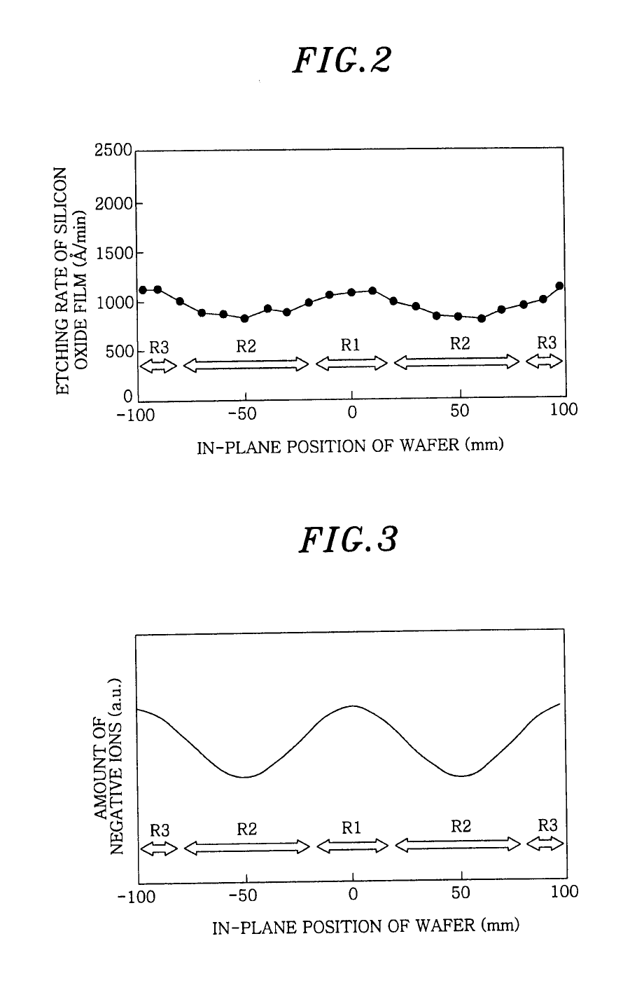

Hereinafter, a result of the etching process performed on the wafer W by the plasma processing apparatus 100 will be explained. Herein, in order to examine an effect of the additional gas, the etching process was performed first by using a plasma generated from only a processing gas without using an additional gas. The result thereof will be described with reference to the drawings. FIG. 2 is a graph showing a test result of an in-plane distribution of an etching rate over the wafer W in case of etching a silicon oxide film formed on the wafer W.

The conditions of the etching process in this test are described as follows. A pressure in the processing chamber 102 was set to 100 mTorr; a temperature of the upper electrode 190 was set to 60° C.; that of the lower electrode 104 was set to 0° C.; and that of the sidewall was set to 50° C. Moreover, a center pressure and an edge pressure of He gas supplied as a backside gas were set to 10 Torr and 35 Torr, respectively. Furthermore, a gap between the upper electrode 190 and the wafer W was adjusted to 25 mm. CF₄ gas as the processing gas was supplied into the processing chamber 102 at a flow rate of 100 sccm. In addition, a high frequency power of 1500 W having a frequency of 60 MHz was applied to the upper electrode 190, and a high frequency power of 100 W having a frequency of 2 MHz was applied to the lower electrode 104. Accordingly, a plasma of CF₄ gas was generated, and the etching process was performed.

FIG. 2 presents a graph obtained by measuring etched amounts at a plurality of points disposed in a diametrical direction of the wafer W by taking the center of the wafer as the origin for a predetermined period of time and calculating etching rates at the respective points.

As illustrated in FIG. 2, when the plasma is generated by introducing CF₄ gas as the processing gas into the processing chamber 102 without introducing the additional gas thereinto, there exist a region where the in-plane etching rate is relatively high and a region where the in-plane etching rate is relatively low, and thus the etching rates are uneven. To be specific, the etching rate is high at a central region R1 around the center of the wafer W (in-plane position of the wafer W is 0 mm) and a peripheral region R3 including the periphery of the wafer W (in-plane position of the wafer W is ±100 mm), whereas the etching rate is low at an intermediate region R2 between the central region R1 and the peripheral region R3. This tendency also occurs, e.g., when the processing gas is introduced separately from different parts of the processing chamber (e.g., the central region and the peripheral region).

(Ion Distribution in Plasma and Etching Rate Uniformity)

Herein, a relationship between the ion distribution in the plasma and the etching rate uniformity is studied further based on the test result shown in FIG. 2. When an electrically negative gas such as CF₄ gas used in this test is used as the processing gas and turned into a plasma, electrons of low energy in the plasma are attached to molecules of the processing gas to thereby generate a large amount of negative ions (e.g., CF₄⁻ or the like). For that reason, negative ions and electrons exist as negatively charged components in the plasma. Further, since the plasma is electrically neutral (quasi-neutral), the distribution of positive ions (CF₃⁺ or the like) follows the distribution of negative ions and electrons in the plasma.

Among the positive ions, the negative ions and the electrons in the plasma, the electrons that obtain energy during the plasma generation reach the surface of the wafer W faster than ions having low speeds. The positive ions are accelerated by a negative potential of the electrons, and highly isotropic etching is performed on the silicon oxide film. In this regard, it may be generally considered that the positive ions mainly contribute to the etching of the silicon oxide film. Therefore, it may be assumed that when the distribution of the positive ions in the plasma is uniform, the etching rate to the silicon oxide film is uniform over the surface of the wafer W.

However, as clearly can be seen from the graph shown in FIG. 2, the in-plane distribution of the etching rate measured in this test includes partial non-zero gradients, which indicates that the distribution of positive ions also includes partial non-zero gradients. Moreover, when the electrically negative gas is used as the processing gas as in this test, the number of negative ions generated is larger than the number of electrons generated. For that reason, it may be considered that negative ions are dominant among negatively charged components. In that case, the distribution of positive ions in the plasma is strongly affected by that of negative ions, that is, the distribution of positive ions follows closely to that of negative ions. Hence, the gradient of the in-plane distribution of the etching rate shown in the graph shown in FIG. 2 is considered to be caused mainly by the gradient of the distribution of negative ions shown in FIG. 3.

As a consequence, the present inventors have found that the in-plane uniformity can be improved by controlling the distribution of positive ions that in turn can be controlled by first increasing the number of negative ions in the plasma and then controlling them. To be specific, it has been found that the distribution of negative ions can be controlled by regulating the flow rate of the additional gas. To do so, the amount of negative ions in the plasma generated from the processing gas and the additional gas is increased by adding to the processing gas as an additional gas an electrically negative gas (gas having molecules which are easily combined with electrons and produce a large amount of negative ions compared to the processing gas) having an electron attachment coefficient greater than that of the processing gas. When the processing gas is a fluorocarbon-based gas such as CF₄ gas or the like, NF₃ gas, SF₆ gas or F₂ gas may be included as a candidate of a gas having an electron attachment coefficient greater than the processing gas. Therefore, these gases can be preferably used as the additional gas.

Especially when the total charge amount of negative ions is substantially the same as that of electrons, or when an absolute value of the total charge amount of negative ions in the plasma which are accumulated at the central region is greater than that of the total charge amount of electrons, an electrically negative gas having an electron attachment coefficient greater than the processing gas is added as an additional gas, so that the distribution of positive ions is strongly affected by that of negative ions. In other words, in that case, the electron distribution can be made negligible by increasing the amount of negative ions especially by adding the additional gas. For that reason, the distribution of positive ions becomes substantially the same as that of negative ions. Moreover, the distribution of negative ions can be uniformly controlled by regulating the flow rate of the additional gas. As a result, the in-plane uniformity of the etching rate can be further improved compared to that of the conventional case.

As such, an electrically negative gas having an electron attachment coefficient greater than that of the processing gas is added to the processing gas to increase the amount of negative ions, and the in-plane distribution of negative ions can be controlled by regulating the flow rate of the additional gas. Accordingly, the in-plane distribution of positive ions can also be controlled. By regulating the flow rate of an electrically negative gas as an additional gas, an ion density in the plasma can be controlled and, hence, the in-plane uniformity of the etching rate can be further improved compared to the conventional case.

In addition, if the additional gas is configured to be introduced into the processing chamber 102 together with the processing gas, the additional gas and the processing gas may be introduced as a gaseous mixture from the same part of the processing chamber 102, or may be introduced separately from different parts of the processing chamber 102.

(Result of Test for Verifying an Effect of Additional Gas)

Hereinafter, a result of a test in which the etching was performed by using a plasma generated by introducing into the processing chamber 102 as an additional gas an electrically negative gas having an electron attachment coefficient greater than that of the processing gas will be described with reference to the drawings.

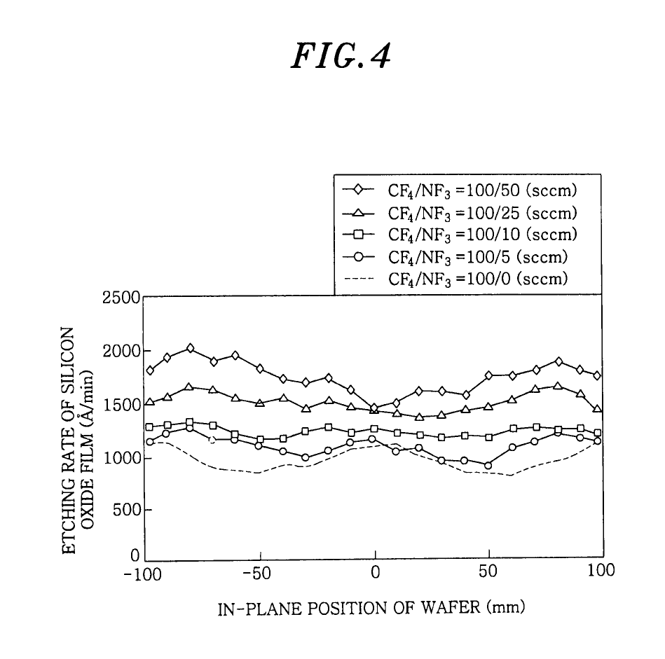

First, the result of the test in which the plasma etching was performed by using CF₄ gas as the processing gas and NF₃ gas as the additional gas is shown in FIG. 4. Herein, the in-plane distribution of the etching rate over the wafer W in case of etching a silicon oxide film formed on the wafer W was checked. FIG. 4 provides a graph showing in-plane distributions of the etching rates measured by performing etching by using a plasma generated while fixing a flow rate of CF₄ gas to 100 sccm and varying flow rates of NF₃ gas to 0 sccm, 5 sccm, 10 sccm, 25 sccm and 50 sccm, respectively. Since other processing conditions are the same as those of the test described in FIG. 2, detailed description thereof will be omitted.

In accordance with the test result shown in FIG. 4, the in-plane uniformity of the etching rate was enhanced when the plasma was generated by using a gaseous mixture obtained by adding NF₃ gas of just 5 sccm to CF₄ gas of 100 sccm, compared to when NF₃ gas was not added (dashed line graph). Further, the etching rate was more uniform over the entire surface of the wafer W when the plasma was generated while increasing the flow rate of NF₃ gas to 10 sccm.

For example, when a plasma is generated by adding NF₃ gas as an additional gas having an electron attachment coefficient greater than CF₄ gas, if the amount of negative ions accumulated at the central region R1 and the peripheral region R3 shown in FIG. 3 reaches a certain level, the negative ions are diffused to the intermediate region R2. As a result, the balance between the density of negative ions in the intermediate region R2 and the density of negative ions in the central region R1 and the peripheral regions R3 is achieved.

That is, when a plasma is generated by introducing into the processing chamber 102 an electrically negative gas as the processing gas (CF₄ gas in this test) and as the additional gas an electrically negative gas (NF₃ gas in this test) having an electron attachment coefficient greater than that of the processing gas, the number of the negative ions in the plasma increases and the distribution thereof becomes more uniform. Accordingly, the distribution of positive ions becomes more uniform. As a result, the in-plane uniformity of the etching rate can be enhanced.

However, in accordance with the test result shown in FIG. 4, the in-plane uniformity of the etching rate is decreased as the flow rate of NF₃ gas is further increased to 25 sccm or 50 sccm. Therefore, in order to improve the in-plane uniformity of the etching rate, it is preferable to set the flow rate ratio of the additional gas to the processing gas to be smaller than or equal to about 1/10. Especially, in the etching conditions of the above test, it is more preferable to add NF₃ gas of about 10 sccm to CF₄ gas of 100 sccm, and this can ensure the most uniform etching rate.

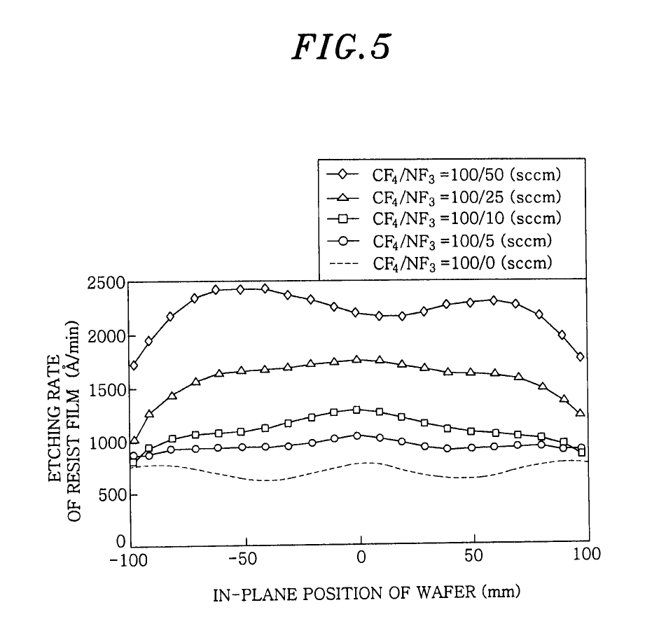

Next, a test was performed by using the processing gas (CF₄ gas) and the additional gas (NF₃ gas) used in the test of FIG. 4. At this time, however, the type of the etching target film was changed. The test result thereof is illustrated in FIG. 5. Herein, an in-plane distribution of an etching rate in case of etching a resist film formed on the wafer W was checked.

In accordance with the test result depicted in FIG. 5, even in a case where the etching target film was changed to a resist film, it was found that the etching rate improved similarly to the case when it was a silicon oxide film. In other words, it was found that when the plasma was generated by adding NF₃ gas of just 5 sccm to CF₄ gas of 100 sccm, the in-plane uniformity of the etching rate was further improved compared to the case where NF₃ gas was not added (dashed line graph).

However, in accordance with the test result shown in FIG. 5, the in-plane uniformity of the etching rate is decreased as the amount of NF₃ gas is further increased. Therefore, in order to enhance the in-plane uniformity of the etching rate, it is preferable to set the flow rate ratio of the additional gas to the processing gas to be smaller than or equal to about 1/10. Especially, in the etching conditions of this test, it is more preferable to add NF₃ gas of about 5 sccm to CF₄ gas of 100 sccm, and this can ensure the most uniform etching rate.

That is, when the plasma is generated by introducing CF₄ gas as the processing gas and NF₃ gas as the additional gas into the processing chamber 102, the in-plane uniformity of the etching rate can be enhanced regardless of the types of the etching target film.

When the etching target film is a silicon oxide film, the flow rate of NF₃ gas which can ensure the most uniform etching rate is 10 sccm. On the other hand, when the etching target film is a resist film, the optimal flow rate thereof is 5 sccm. That is, although the optimal flow rate of the additional gas varies depending on the types of the etching target film, the etching rate is enhanced by setting the flow rate ratio of the additional gas to the processing gas to be smaller than or equal to about 1/10. Further, the flow rate ratio of the additional gas may be controlled depending on the types of the etching target film, or may be fixed regardless of the types of the etching target film. When it is fixed, other processing conditions may be controlled.

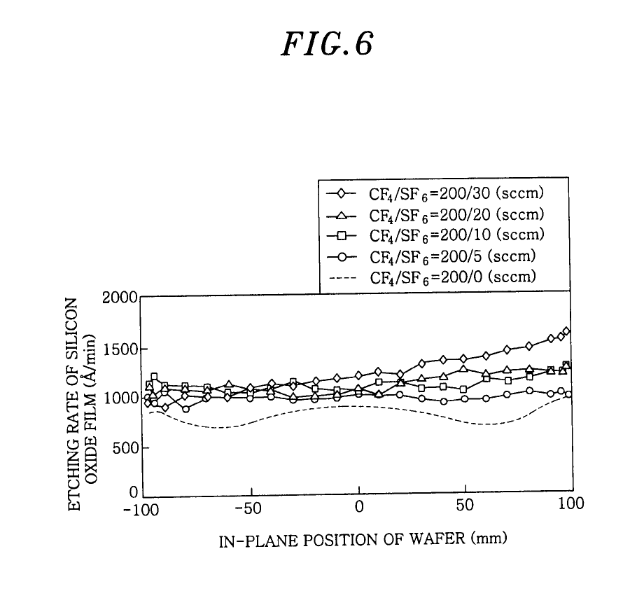

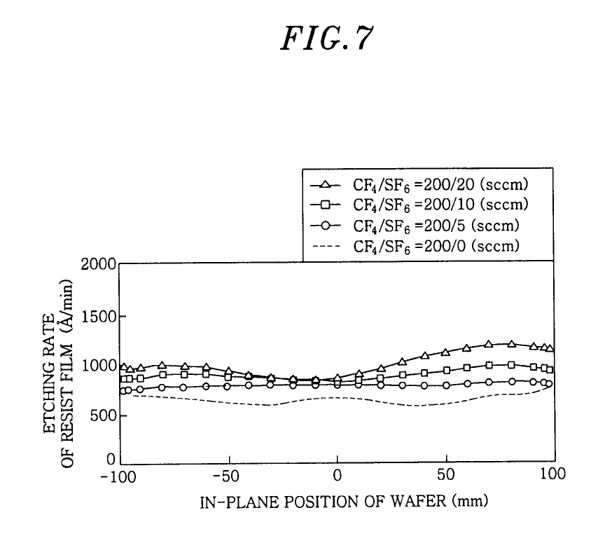

Next, the plasma etching was performed by using a different additional gas. Test results thereof are shown in FIGS. 6 and 7. FIG. 6 is a graph showing in-plane distributions of etching rates over the wafer W in case of etching a silicon oxide film on the wafer W as shown in FIG. 4 by using SF₆ gas as an additional gas. To be specific, the etching was performed by a plasma generated while fixing a flow rate of CF₄ gas to 200 sccm and varying the flow rates of SF₆ gas to 0 sccm, 5 sccm, 10 sccm, 20 sccm and 30 sccm. The intra-wafer distributions of the etching rates measured at that time are shown as a graph.

FIG. 7 offers a graph describing in-plane distributions of etching rates in case of etching a resist film on a wafer as shown in FIG. 5 by using SF₆ gas as an additional gas. To be specific, the etching was performed by using a plasma generated while fixing a flow rate of CF₄ gas to 200 sccm and varying the flow rates SF₆ gas to 0 sccm, 5 sccm, 10 sccm and 20 sccm. Besides, in the tests of FIGS. 6 and 7, the high frequency power of 500 W having a frequency of 60 MHz was applied to the upper electrode 190. Since the other processing conditions are the same as those of the test of FIG. 2, detailed description thereof will be omitted.

In accordance with the test results illustrated in FIGS. 6 and 7, it was found that when just 5 sccm of SF₆ gas was added to 200 sccm of CF₄ gas, the etching rate was enhanced regardless of whether the etching target film was a silicon oxide film or a resist film, similarly to the case when NF₃ gas was used as an additional gas as shown in FIGS. 4 and 5. In other words, when the plasma was generated by adding about 5 sccm of SF₆ gas to 200 sccm of CF₄ gas, the in-plane uniformity of the etching rate was enhanced compared to the case where SF₆ gas was not added (dashed line graph).

However, in the test results shown in FIGS. 6 and 7, the in-plane uniformities of the etching rates are decreased as the amounts of SF₆ gas are further increased. Therefore, in order to improve the in-plane uniformity of the etching rate, it is preferable to set the flow rate ratio of the additional gas to the processing gas to be smaller than or equal to about 1/10. Especially, in the etching conditions of this test, it is more preferable to add SF₆ gas of about 5 sccm to CF₄ gas of 200 sccm regardless of the types of the etching target film, and this can ensure the most uniform etching rate.

That is, when the plasma is generated by introducing CF₄ gas as the processing gas and SF₆ gas as the additional gas into the processing chamber 102, the in-plane uniformity of the etching rate can be enhanced regardless of the types of the etching target film.

Moreover, in the above-described tests, the pressure in the processing chamber 102 was controlled to be maintained at a relatively high level of 100 mTorr. In such environment, the energy of electrons in the plasma is decreased. Therefore, molecules of the additional gas easily capture electrons, and this leads to generation of a large amount of negative ions. On the contrary, the energy of electrons in the plasma is increased when the pressure in the processing chamber 102 is lowered. Accordingly, the amount of negative ions in the plasma is likely to be decreased. In that case, it is preferable to increase the amount of negative ions in the plasma by controlling the processing conditions, such as by changing the type of the additional gas or increasing the flow rate thereof.

In accordance with the above-described embodiments, the plasma is generated by introducing into the processing chamber 102 an electrically negative gas, e.g., CF₄ gas, as a processing gas and an electrically negative gas, e.g., NF₃ gas, having an electron attachment coefficient greater than that of the processing gas as an additional gas, so that a uniform distribution of negative ions and that of positive ions in the plasma can be obtained. As a consequence, the in-plane uniformity of the etching rate can be enhanced.

While the invention has been shown and described with respect to the embodiments, the present invention is not limited thereto. It will be understood by those skilled in the art that various changes and modification may be made without departing from the scope of the invention as defined in the following claims.

For example, the present invention is not limited to an etching process, and may also be applied to various types of plasma processing for performing a predetermined processing such as an ashing process, a film forming process or the like on a substrate to be processed by using a plasma generated from a processing gas introduced into a processing chamber. Further, the plasma processing apparatus to which the present invention is applicable is not limited to the plasma etching apparatus shown in FIG. 1, and may also be applied to various types of plasma processing apparatuses such as a plasma CVD apparatus, a plasma ashing apparatus and the like as long as it is an apparatus capable of processing a substrate to be processed by using a plasma of an electrically negative gas as a processing gas.

### INDUSTRIAL APPLICABILITY

The present invention can be applied to a plasma processing method and a plasma processing apparatus for performing a predetermined plasma processing on a substrate to be processed.

What is claimed is:

1. A plasma processing method for performing a predetermined plasma processing on a substrate to be processed by using a plasma generated by introducing an electrically negative gas as a processing gas into a processing chamber, wherein an electrically negative gas having an electron attachment coefficient greater than that of the processing gas is introduced as an additional gas together with the processing gas into the processing chamber to thereby generate the plasma, and an ion density in the plasma is controlled by regulating a flow rate of the additional gas relative to that of the processing gas.

2. The plasma processing method of claim 1, wherein the flow rate of the additional gas introduced into the processing chamber is smaller than or equal to 1/10 of a flow rate of the processing gas.

3. The plasma processing method of claim 2, wherein the processing gas is a fluorocarbon-based gas.

4. The plasma processing method of claim 3, wherein the additional gas is selected from NF₃ gas, SF₆ gas and F₂ gas.

5. A plasma processing apparatus for performing a predetermined plasma processing on a substrate to be processed by using a plasma generated by introducing as a processing gas an electrically negative gas into a processing chamber, the plasma processing apparatus comprising:
a processing gas supply system for supplying the processing gas into the processing chamber;
an additional gas supply system for supplying as an additional gas an electrically negative gas having an electron attachment coefficient greater than that of the processing gas into the processing chamber; and
a control unit for controlling an ion density in the plasma by regulating a flow rate of the additional gas relative to that of the processing gas while generating the plasma by introducing into the processing chamber the processing gas and the additional gas from the processing gas supply system and the additional gas supply system, respectively.

6. The plasma processing apparatus of claim 5, wherein the flow rate of the additional gas introduced into the processing chamber is smaller than or equal to 1/10 of a flow rate of the processing gas.
